(19) United States
(12) Patent Application Publication
(10) Pub. No.: US 2022/0085024 A1
(43) Pub. Date: Mar. 17, 2022

(54) DYNAMIC RANDOM ACCESS MEMORY AND MANUFACTURING METHOD THEREOF

(71) Applicant: CHANGXIN MEMORY TECHNOLOGIES, INC., Hefei City (CN)

(72) Inventors: Sen Li, Hefei (CN); Qiang Wan, Hefei (CN); Tao Liu, Hefei (CN); Penghui Xu, Hefei (CN)

(21) Appl. No.: 17/469,984

(22) Filed: Sep. 9, 2021

Related U.S. Application Data
(63) Continuation of application No. PCT/CN2021/104831, filed on Jul. 6, 2021.

(30) Foreign Application Priority Data
Sep. 16, 2020 (CN) 202010974516.1

(51) Int. Cl. H01L 27/108

(52) U.S. Cl. CPC H01L 27/10808; H01L 27/10852

(57) ABSTRACT

A Dynamic Random Access Memory (DRAM) and a manufacturing method thereof are provided. The DRAM comprises a substrate and connection pads and capacitors disposed on the substrate. Here, the capacitor comprises a first electrode layer; the first electrode layer is provided with an extension part extending towards the substrate, and the extension part is coated on a top surface and a side surface of the connection pad.

### CROSS-REFERENCE TO RELATED APPLICATIONS

The present application is a continuation of International Patent Application No. PCT/CN2021/104831, filed on Jul. 6, 2021, which claims priority to Chinese patent application No. 202010974516.1, filed to the China National Intellectual Property Administration on Sep. 16, 2020 and entitled “Dynamic Random Access Memory and Manufacturing Method Thereof”. The disclosures of International Patent Application No. PCT/CN2021/104831 and Chinese patent application No. 202010974516.1 are hereby incorporated by reference in their entireties.

### BACKGROUND

A DRAM is a semiconductor memory for randomly writing in and reading data at high speed, and is widely applied to a data storage apparatus or device. The DRAM may generally include a substrate and connection pads and capacitors disposed on the substrate. Herein, the connection pad is provided with a bottom surface towards the substrate and a top surface away from the substrate, and an end, close to the substrate, of a first electrode layer of the capacitor is electrically connected with the top surface of the connection pad.

However, contact resistance between the first electrode layer of the capacitor and the connection pad is relatively high, thereby causing signal delay easily and influencing the performance of the DRAM. Moreover, in a process of forming a capacitive structure, as a capacitive hole has a high depth-to-width ratio, the collapse risk of the capacitor is relatively easy to occur in a subsequent manufacturing process.

### SUMMARY

The present disclosure relates to the technical field of semiconductors, and in particular relates to a Dynamic Random Access Memory (DRAM) and a manufacturing method thereof.

A first aspect of the embodiments of the present disclosure provides a DRAM, which includes a substrate, connection pads and capacitors, each connection pad is disposed on the substrate and is provided with a bottom surface towards the substrate and a top surface away from the substrate, and the bottom surface of the connection pad makes contact with the substrate. The capacitors are disposed on the respective connection pads, and each capacitor is provided with a first electrode layer, the first electrode layer is provided with an extension part extending towards the substrate, and the extension part is coated on a top surface and a side surface of the connection pad.

A second aspect of the embodiments of the present disclosure provides a manufacturing method of a DRAM, which may include the following steps. A substrate is provided. Connection pads are formed on the substrate, each connection pad having a bottom surface towards the substrate and a top surface away from the substrate, and the bottom surface of the connection pad making contact with the substrate. Capacitors are formed on the respective connection pads, each capacitor having a first electrode layer, the first electrode layer having an extension part extending towards the substrate, and the extension part covering a top surface and a side surface of the connection pad.

### BRIEF DESCRIPTION OF THE DRAWINGS

FIG. 1 is a schematic structural diagram of a DRAM in a related art.

FIG. 2 is a first schematic structural diagram of a DRAM provided by the first embodiment of the present disclosure.

FIG. 3 is a second schematic structural diagram of a DRAM provided by the first embodiment of the present disclosure.

FIG. 4 is a first flowchart of a manufacturing method of a DRAM provided by the second embodiment of the present disclosure.

FIG. 5 is a schematic diagram of forming dielectric structures and connection pads in a manufacturing method of a DRAM provided by the second embodiment of the present disclosure.

FIG. 6 is a top view of forming dielectric structures and connection pads in a manufacturing method of a DRAM provided by the second embodiment of the present disclosure.

FIG. 7 is a second flowchart of a manufacturing method of a DRAM provided by the second embodiment of the present disclosure.

FIG. 8 is a schematic diagram of forming a first stacked structure in a manufacturing method of a DRAM provided by the second embodiment of the present disclosure.

FIG. 9 is a third flowchart of a manufacturing method of a DRAM provided by the second embodiment of the present disclosure.

FIG. 10 is a schematic diagram of forming first protrusions in a manufacturing method of a DRAM provided by the second embodiment of the present disclosure.

FIG. 11 is a top view of forming first protrusions in a manufacturing method of a DRAM provided by the second embodiment of the present disclosure.

FIG. 12 is a schematic diagram of forming an etching layer in a manufacturing method of a DRAM provided by the second embodiment of the present disclosure.

FIG. 13 is a top view of forming an etching layer in a manufacturing method of a DRAM provided by the second embodiment of the present disclosure.

FIG. 14 is a first schematic diagram of forming annular grooves in a manufacturing method of a DRAM provided by the second embodiment of the present disclosure.

FIG. 15 is a fourth flowchart of a manufacturing method of a DRAM provided by the second embodiment of the present disclosure.

FIG. 16 is a second schematic diagram of forming annular grooves in a manufacturing method of a DRAM provided by the second embodiment of the present disclosure.

FIG. 17 is a schematic diagram of patternizing a first photoresist layer in a manufacturing method of a DRAM provided by the second embodiment of the present disclosure.

FIG. 18 is a top view of patternizing a first photoresist layer in a manufacturing method of a DRAM provided by the second embodiment of the present disclosure.

FIG. 19 is a first schematic diagram of forming a filler layer in a manufacturing method of a DRAM provided by the second embodiment of the present disclosure.

FIG. 20 is a second schematic diagram of forming a filler layer in a manufacturing method of a DRAM provided by the second embodiment of the present disclosure.

FIG. 21 is a first schematic diagram of forming a second stacked structure in a manufacturing method of a DRAM provided by the second embodiment of the present disclosure.

FIG. 22 is a second schematic diagram of forming a second stacked structure in a manufacturing method of a DRAM provided by the second embodiment of the present disclosure.

FIG. 23 is a fifth flowchart of a manufacturing method of a DRAM provided by the second embodiment of the present disclosure.

FIG. 24 is a first schematic diagram of forming openings in a manufacturing method of a DRAM provided by the second embodiment of the present disclosure.

FIG. 25 is a second schematic diagram of forming openings in a manufacturing method of a DRAM provided by the second embodiment of the present disclosure.

FIG. 26 is a first schematic diagram of forming capacitive holes and annular grooves in a manufacturing method of a DRAM provided by the second embodiment of the present disclosure.

FIG. 27 is a second schematic diagram of forming capacitive holes and annular grooves in a manufacturing method of a DRAM provided by the second embodiment of the present disclosure.

FIG. 28 is a top view of forming capacitive holes and annular grooves in a manufacturing method of a DRAM provided by the second embodiment of the present disclosure.

FIG. 29 is a first schematic diagram of forming a first electrode layer and an extension part in a manufacturing method of a DRAM provided by the second embodiment of the present disclosure.

FIG. 30 is a second schematic diagram of forming a first electrode layer and an extension part in a manufacturing method of a DRAM provided by the second embodiment of the present disclosure.

FIG. 31 is a top view of forming a first electrode layer and an extension part in a manufacturing method of a DRAM provided by the second embodiment of the present disclosure.

FIG. 32 is a sixth flowchart of a manufacturing method of a DRAM provided by the second embodiment of the present disclosure.

FIG. 33 is a schematic structural diagram of forming second opening regions in a manufacturing method of a DRAM provided by the second embodiment of the present disclosure.

### DETAILED DESCRIPTION

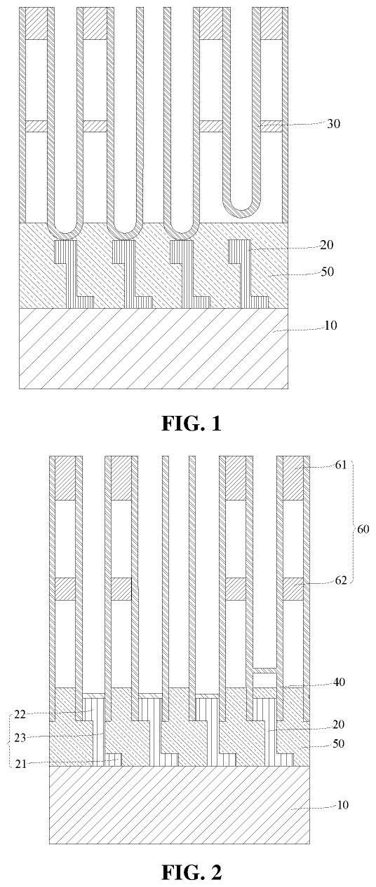

In an actual working process, the inventor of the present disclosure finds that: as illustrated in FIG. 1, an end, close to a substrate 10, of a first electrode layer 30 of each capacitor is disposed on a top surface of a respective connection pad 20. A contact area between the first electrode layer 30 and the connection pad 20 is relatively small, which results in that contact resistance between the first electrode layer 30 and the connection pad 20 is relatively large, and the contact resistance will cause a DRAM to have signal delay, thereby reducing the performance of the DRAM.

Moreover, when a capacitive hole of the capacitor has a high depth-to-width ratio and a contact area between the first electrode layer 30 and the connection pad 20 is relatively small, the collapse risk of the capacitive hole easily occurs, thereby influencing the performance of the DRAM.

Aiming at the above technical problems, the embodiments of the present disclosure provide a DRAM and a manufacturing method thereof. As an extension part extending towards a substrate is disposed on a first electrode layer, and the extension part is coated on a top surface and a side surface of a connection pad at the same time, a contact area between the first electrode layer and the connection pad may be increased, contact resistance between the first electrode layer and the connection pad may be reduced, thus signal delay of the DRAM may be reduced, and the performance of the DRAM may be improved. Meanwhile, the extension part may also increase the acting force between the capacitive hole and the connection pad, so that the collapse risk of the capacitor in the subsequent manufacturing process is reduced.

In order to make the above objectives, features and advantages of the embodiments of the present disclosure more apparent and understandable, the technical solutions in the embodiments of the present disclosure will be clearly and completely described below in combination with the drawings in the embodiments of the present disclosure. It is apparent that the described embodiments are not all embodiments but merely part of embodiments of the present disclosure. On the basis of the embodiments of the present disclosure, all other embodiments obtained by those of ordinary skilled in the art without creative work shall fall within the scope of protection of the present disclosure.

### First Embodiment

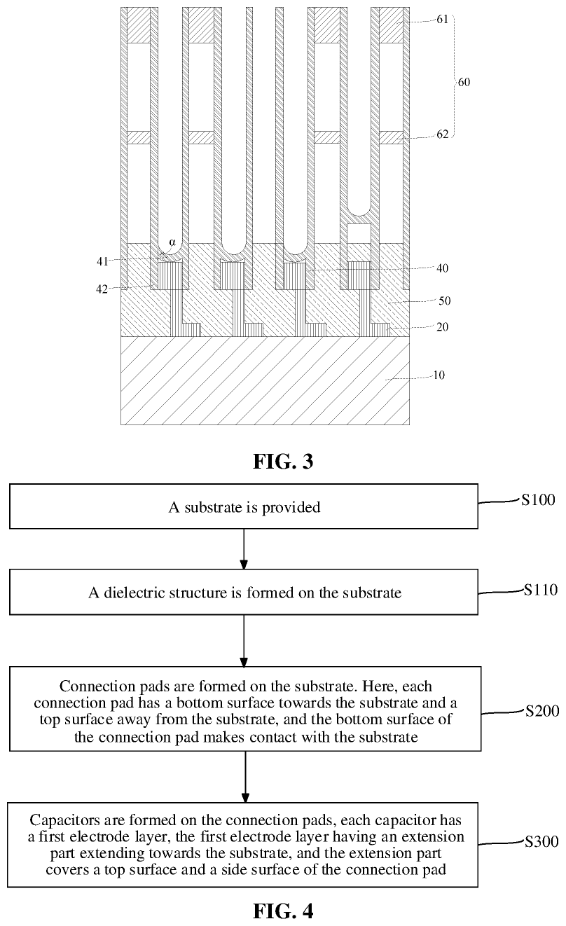

As illustrated in FIG. 2 and FIG. 3, the embodiments of the present disclosure provide a DRAM, which may include a substrate 10, the substrate 10 serving as a supporting part of the DRAM and configured to support other parts disposed thereon, herein, the substrate 10 may be made of a semiconductor material, and the semiconductor material may be one or more of silicon, germanium, a silicon germanium compound and a silicon carbon compound.

Connection pads 20 and capacitors electrically connected with the respective connection pad 20 are disposed on the substrate 10. The connection pad 20 has a bottom surface towards the substrate 10 and a top surface away from the substrate 10. Herein, the bottom surface of the connection pad 20 makes contact with the substrate 10, so that the capacitor is electrically connected with an active region of the substrate 10, and thus signal transmission between the active region of the substrate 10 and the capacitors is realized.

The contact between the bottom surface of the connection pad 20 and the substrate 10 may be understood as direct contact or indirect contact. For example, necessary structures of the DRAM such as transistors, word lines and capacitor contact windows (not illustrated in the figure) may be disposed in the substrate 10. Herein, an end of the capacitor contact window is electrically connected with the active region of the substrate 10, and the other end of the capacitor contact window is electrically connected with the bottom surface of the connection pad 20. Through arrangement of the capacitor contact window in the embodiment, electrical connection between the capacitor and the active region in the substrate 10 may be realized, and signal transmission is convenient.

The active region of the substrate 10 refers to a region used for setting signal routing, which is used for being electrically connected with the capacitor and providing a control signal for the capacitor. Moreover, there may be a plurality of active regions of the substrate 10, an isolation structure is disposed among the plurality of active regions, and the isolation structure is configured to enable adjacent active regions to be insulated mutually.

In the embodiment, as the connection pad 20 is disposed between the capacitor contact window and the capacitor, a contact area between the capacitor contact window and the capacitor may be increased by utilizing the connection pad 20, so that contact resistance between the capacitor contact window and the capacitor is reduced, thus, signal delay of the DRAM is reduced, and the performance of the DRAM is improved. Moreover, areas of the top surface and the bottom surface of the connection pad 20 are greater than a contact area between the capacitor contact window and the capacitor. Due to the design, in a process of manufacturing the DRAM, the alignment speed of the capacitor and the connection pad is greater than the direct alignment speed of the capacitor and the capacitor contact window, so that the manufacturing efficiency is increased.

The capacitor may include a first electrode layer 30, the first electrode layer 30 is provided with an extension part 40 extending towards the substrate, and the extension part 40 is coated on a top surface and a side surface of the connection pad 20, so that a contact area between the first electrode layer 30 and the connection pad 20 may be increased, contact resistance between the first electrode layer 30 and the connection pad 20 may be reduced, thus signal delay of the DRAM may be reduced, and the performance of the DRAM may be improved. Moreover, due to increasing of a contact area between the first electrode layer 30 and the connection pad 20, collapse of the capacitor may be effectively prevented in a subsequent process.

The extension part 40 and the first electrode layer 30 of the capacitor may be made of the same material, so that the first electrode layer 30 of the capacitor may be ensured to have basically same resistance at various positions, signal delay of the DRAM is reduced, and the performance of the DRAM is improved. For example, the extension part 40 and the first electrode layer 30 may be one or more of titanium nitride, tungsten, tungsten titanium, aluminum, copper or metal silicide.

The extension part 40 and the first electrode layer 30 may be an integrated structure and may also be a split structure. When the extension part 40 and the first electrode layer 30 may be an integrated structure, the first electrode layer 30 and the extension part 40 may be manufactured by adopting a same manufacturing process at the same time, so that the manufacturing process of the first electrode layer 30 and the extension part 40 is simplified, and the production cost is reduced.

The shape of the extension part 40 is adaptive to the shape of a joint of the connection pad 20 and the extension part 40. For example, the shape of the joint of the connection pad 20 and the extension part 40 is cylindrical, correspondingly, the shape of the extension part 40 may be a circular structure with an opening, at least part of the connection pad 20 extends into the circular structure, so that the side surface of the connection pad 20 is attached to the inside surface of the circular structure, i.e., the circular structure covers at least part of the side surface of the connection pad 20.

In some embodiments, continuously referring to FIG. 3, the extension part 40 may include a first extension part 41 and a second extension part 42, the first extension part 41 is coated on a top surface of the connection pad 20, the second extension part 42 is coated on a side surface of the connection pad 20, and the first extension part 41 and the second extension part 42 have an included angle, which is between 50 degrees and 90 degrees.

Herein, the included angle is alpha as illustrated in FIG. 3. The included angle between the first extension part 41 and the second extension part 42 is limited by the embodiment. When the included angle is 90 degrees, a bottom surface of the first extension part 41 is completely attached to a top surface of the connection pad, so that a contact area between the extension part 40 and the connection pad 20 may be increased to the most extent. While contact resistance between the first electrode layer 30 and the connection pad 20 is reduced and signal delay is reduced, the acting force between the first electrode layer 30 and the connection pad 20 may also be increased, thereby preventing collapse of the capacitor.

In some embodiments, the connection pad 20 may include a first connection part 21, a second connection part 22 and a transition part 23, herein, the transition part 23 is disposed between the first connection part 21 and the second connection part 22, an end of the transition part 23 is connected with the first connection part 21, and the other end of the transition part 23 is connected with the second connection part 22.

The first connection part 21 is electrically connected with the capacitor contact window, the second connection part 22 is electrically connected with the first electrode layer 30, electrical connection between the capacitor contact window and the first electrode layer 30 is realized through the connection pad 20, so that a signal of the active region on the substrate 10 is transmitted to the capacitor, and thus the storage function of the capacitor is realized.

In the connection pad 20, a plane parallel to the substrate 10 is used as a section, the sectional area of the transition part 23 is smaller than the sectional area of the first connection part 21 and smaller than the sectional area of the second connection part 22. In the embodiment, the transition part 23 is configured to realize connection between the first connection part 21 and the second connection part 22, and cannot make direct contact with the capacitor contact window or the first electrode layer 30, therefore, the sectional area of the transition part 23 in the embodiment is relatively small, so that the area occupied by the connection pad 20 may be reduced, and thus the size of the DRAM is reduced. Meanwhile, the sectional area of the first connection part 21 and the sectional area of the second connection part 22 are larger than the sectional area of the transition part 23, in a process of manufacturing the DRAM, the connection pad and the capacitor contact window may be aligned rapidly, and the capacitor and the connection pad may be aligned rapidly, so that the manufacturing efficiency is increased.

Moreover, as the sectional area of the first connection part 21 is larger than the sectional area of the transition part 23, a contact area between the first connection part 21 and the capacitor contact window may be increased, the contact resistance between the first connection part 21 and the capacitor contact window may be reduced, so that the signal delay between the first connection part 21 and the capacitor contact window is reduced, and the performance of the DRAM is improved. As the sectional area of the second connection part 22 is larger than the sectional area of the transition part 23, a contact area between the second connection part 22 and the first electrode layer 30 may be increased, the contact resistance between the second connection part 22 and the first electrode layer 30 may be reduced, so that signal delay between the second connection part 22 and the first electrode layer 30 is reduced, and the performance of the DRAM is improved.

The extension part 40 in the embodiment may cover a top surface, where the second connection part 22 makes contact with the first electrode layer 30, and a side surface of the second connection part 22, so that a contact area between the second connection part 22 and the first electrode layer 30 may be increased, contact resistance between the second connection part 22 and the first electrode layer 30 may be reduced, thus, signal delay between the second connection part 22 and the first electrode layer 30 is reduced, and the performance of the DRAM is improved.

The operation that the extension part 40 covers the side surface of the second connection part 22 may be understood as: the extension part 40 surrounds the second connection part 22, and the inside surface of the extension part 40 is attached to the side surface of the second connection part 22.

The bottom surface of the extension part 40 may be aligned to the bottom surface of the second connection part 22, at this time, the extension part 40 covers all regions of the side surface of the second connection part 22. The extension part 40 and the bottom surface of the second connection part 22 may also be separated by a predetermined distance, at this time, the extension part 40 covers part of regions of the side surface of the second connection part 22.

The DRAM provided by the embodiments may also include a dielectric structure 50, the dielectric structure 50 is disposed between the substrate 10 and the capacitor, moreover, the connection pad 20 is disposed in the dielectric structure 50, so that the connection pad 20 may be insulated from other parts, and normal operation of the DRAM is ensured. Herein, other parts may be parts in the DRAM, besides the capacitor and parts in the active region.

Herein, the dielectric structure 50 may include a single film layer and may also include a plurality of film layers that are stacked in sequence. When the dielectric structure 50 may include the plurality of film layers, materials of adjacent film layers may be same and may also be different. Exemplarily, the dielectric structure 50 may include three film layers that are stacked in sequence, and materials of the three film layers may be silicon oxide, silicon nitride and silicon oxynitride.

In some embodiments, the capacitor may also include a second electrode layer (not illustrated in the figure), which is disposed in a layer different from a layer of the first electrode layer 30, and the capacitor may also include a dielectric layer (not illustrated in the figure), which is disposed between the first electrode layer 30 and the second electrode layer.

The second electrode layer is disposed on one side, away from the substrate 10, of the first electrode layer 30, and has an overlapped region with the first electrode layer 30, so that capacitance will be formed between the first electrode layer 30 and the second electrode layer for data storage.

In the embodiment, the condition that the first electrode layer 30 and the second electrode layer have the overlapped region may be understood as: a projection of the second electrode layer on the first electrode layer 30 is completely superposed with the first electrode layer 30, or partly superposed.

There are many choices of shapes of the first electrode layer 30 and the second electrode layer. For example, the first electrode layer and the second electrode layer may be two square plate bodies disposed in different layers. For another example, by taking a plane vertical to the substrate as a longitudinal section, the shape of the longitudinal section of the first electrode layer 30 may be a U shape with a top opening. As illustrated in FIG. 2, the bottom surface of the first electrode layer 30 and the top surface of the connection pad 20 are in line contact. For another example, the shape of the longitudinal section of the first electrode layer 30 may be rectangular with a top opening, i.e., as illustrated in FIG. 3, the bottom surface of the first electrode layer 30 is attached to the top surface of the second connection part 22, so that a contact area between the first electrode layer 30 and the connection pad 20 may be increased, and contact resistance between the first electrode layer 30 and the connection pad 20 may be reduced.

The dielectric layer is configured to realize insulation between the first electrode layer 30 and the second electrode layer, herein, the material of the dielectric layer may be one or more of silicon oxide, silicon nitride and silicon oxynitride.

In some embodiments, the DRAM disclosed by the embodiment may include a plurality of capacitors, the plurality of capacitors are disposed on the dielectric structure 50 at intervals, moreover, a supporting layer 60 is disposed between adjacent capacitors, herein, on one hand, the plurality of capacitors may be separated by the supporting layer 60, so that the plurality of capacitors may be controlled independently, on the other hand, the supporting layer 60 may also be configured to support the capacitors, so that the structural strength of the capacitors is improved.

As illustrated in FIG. 3, each of the capacitors is provided with a bottom towards the substrate and a top away from the substrate, the supporting layer 60 may include a top supporting layer 61, an intermediate supporting layer 62 and a bottom supporting layer (not illustrated in the figure), herein, the top supporting layer 61 is located among a plurality of capacitors, moreover, the top surface of the top supporting layer 61 is aligned to the top of the capacitor, the bottom surface of the top supporting layer 61 and the dielectric structure 50 are disposed at intervals, the intermediate supporting layer 62 is located between the top supporting layer 61 and the dielectric structure 50, and the bottom supporting layer is disposed in the dielectric structure 50. A three-point support mode is adopted in the embodiment, so that the structural strength of the capacitor may be ensured.

### Second Embodiment

The embodiments of the present disclosure further provide a manufacturing method of a DRAM, which may include the following steps.

At S100, a substrate 10 is provided.

Herein, the substrate 10 is used as a supporting part of the DRAM and configured to support other parts disposed thereon, herein, the substrate 10 may be made of a semiconductor material, for example, the semiconductor material may be one or more of silicon, germanium, a silicon germanium compound and a silicon carbon compound.

At S200, connection pads 20 is formed on the substrate 10. The connection pad 20 has a bottom surface towards the substrate 10 and a top surface away from the substrate 10, and the bottom surface of the connection pad 20 makes contact with the substrate 10.

Herein, the material of the connection pads 20 may be one or more of titanium nitride, tungsten, tungsten titanium, aluminum, copper or metal silicide, so that electrical connection between an active region of the substrate and capacitors is realized.

Exemplarily, before the step of forming the connection pads 20 on the substrate 10, the operation may also include S110.

As illustrated in FIG. 4, a dielectric structure 50 is formed on the substrate 10, afterwards, the connection pads 20 are formed in the dielectric structure 50, through arrangement of the dielectric structure 50, mutual insulation among the connection pads 20 and other parts on the substrate 10 besides the active region may be ensured.

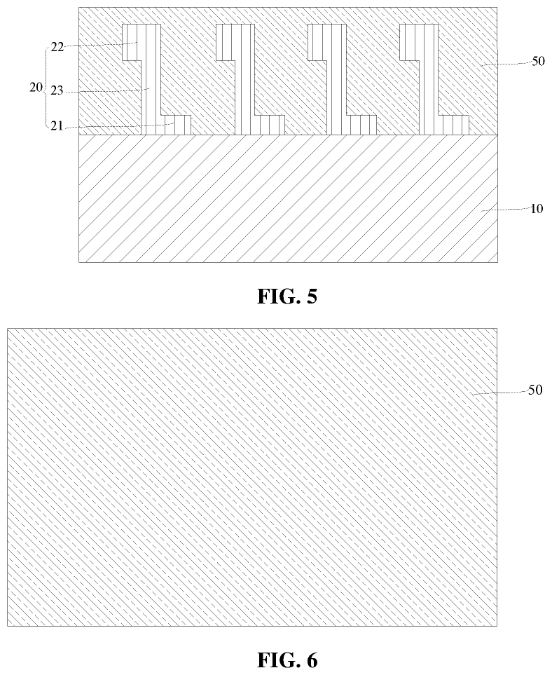

In the step, a layer of dielectric structure may be deposited on the substrate through chemical deposition, physical deposition or an evaporation mode, then, connecting holes for containing the respective connection pads are formed on the dielectric structure by adopting a composition process, and a conductive material is deposited in the connecting hole in a deposition manner to form the connection pads at last. Structures of the dielectric structure 50 and the connection pads 20 in the embodiment are as illustrated in FIG. 5 and FIG. 6.

At S300, capacitors are formed on the respective connection pads 20. The capacitor has a first electrode layer 30, the first electrode layer 30 has an extension part 40 extending towards the substrate 10, and the extension part 40 covers a top surface and a side surface of the connection pad 20.

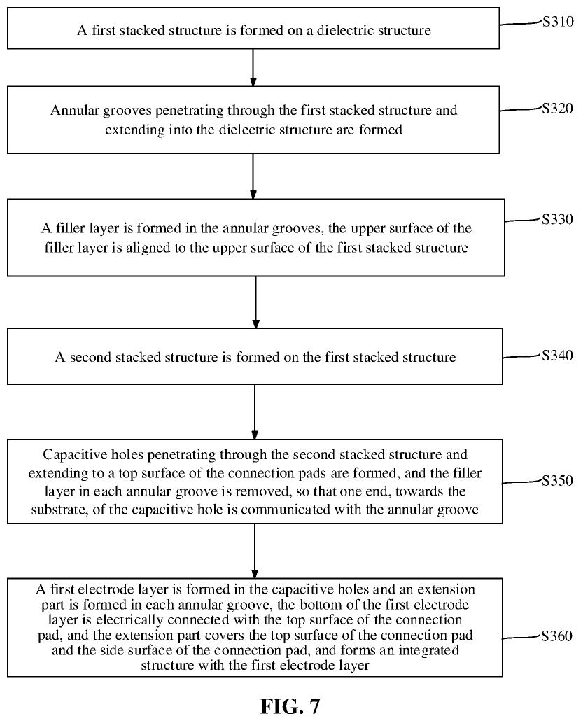

The S300 may be carried out by adopting a manner illustrated in a process flowchart in FIG. 7. Exemplarily.

At S310, a first stacked structure 70 is formed on the dielectric structure 50.

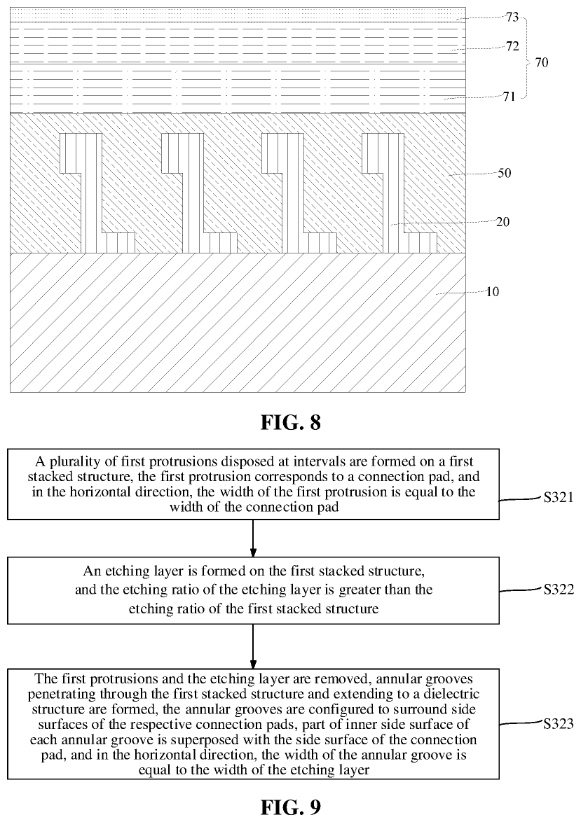

In the step, the first stacked structure 70 may be formed on the dielectric structure 50 through an atomic layer deposition process or a chemical vapor deposition process, herein, the first stacked structure 70 may include a first oxide layer 71, a first mask layer 72 and a first silicon oxynitride layer 73, thereby forming a structure as illustrated in FIG. 8. It is to be noted that the first oxide layer 71 in the embodiment may be silicon oxide or zirconium oxide.

At S320, an annular groove penetrating through the first stacked structure 70 and extending into the dielectric structure 50 is formed.

Exemplarily, as illustrated in FIG. 9, the S320 may include the following steps.

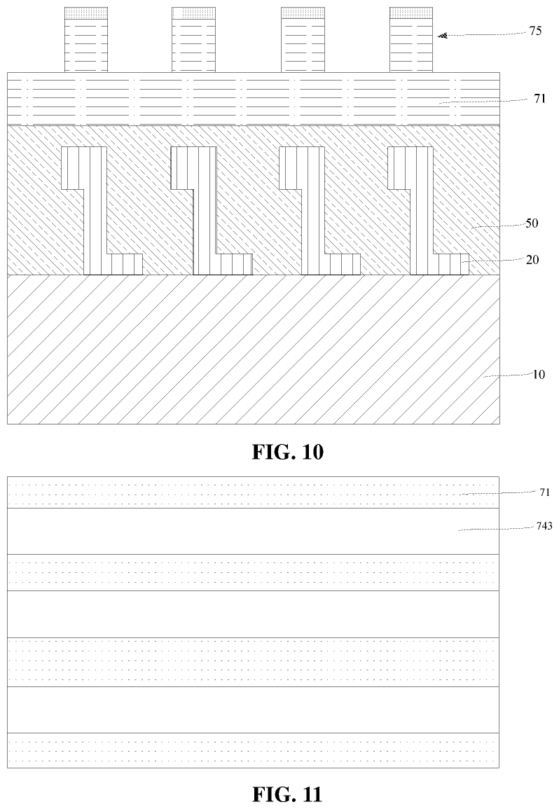

At S321, a plurality of first protrusions 75 disposed at intervals are formed on the first stacked structure 70, as the plurality of first protrusions 75 disposed at intervals are formed on the first stacked structure and the first protrusion 75 corresponds to the connection pad 20, and in the horizontal direction, the width of the first protrusion 75 is equal to the width of the connection pad 20, thereby forming a structure as illustrated in FIG. 10 and FIG. 11.

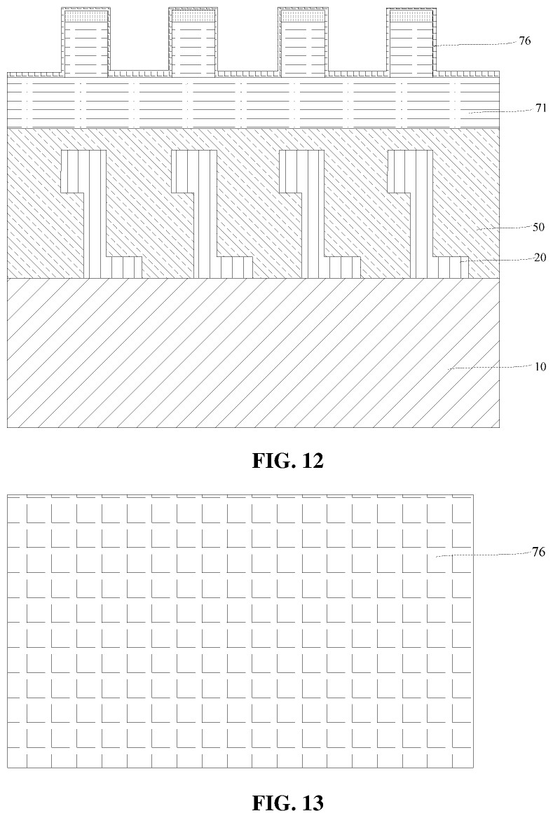

At S322, an etching layer 76 is formed on the first stacked structure 70, thereby forming a structure as illustrated in FIG. 12 and FIG. 13. In the step, the etching ratio of the etching layer 76 is greater than the etching ratio of the first stacked structure 70.

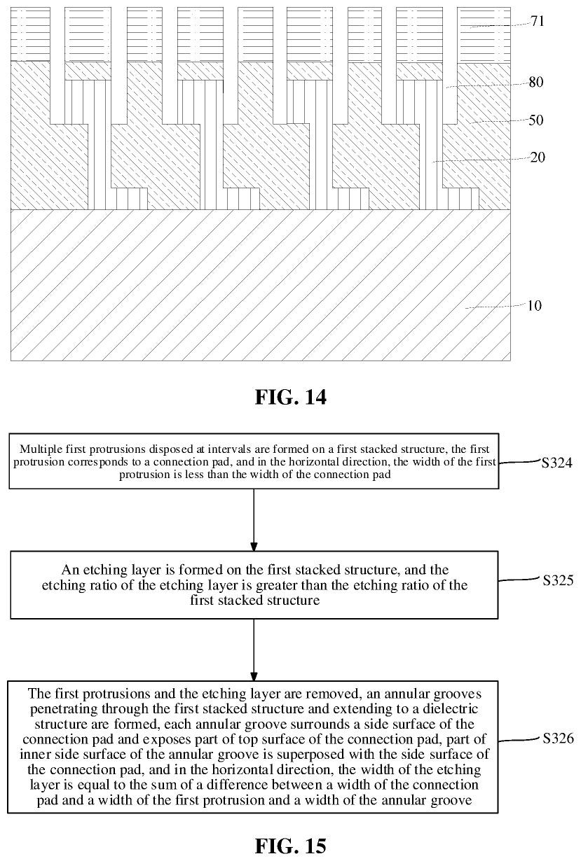

At S323, the first protrusions 75 and the etching layer 76 are removed, and the annular grooves 80 penetrating through the first stacked structure 70 and extending to the dielectric structure 50 are formed. As illustrated in FIG. 14, the annular groove 80 is configured to surround a side surface of the connection pad 20, part of inner side surface of the annular groove 80 is superposed with the side surface of the connection pad 20, and in the horizontal direction, the width of the annular groove 80 is equal to the width of the etching layer 76.

In the step, the process of forming the annular grooves 80 is carried out by adopting a Self-Aligned Double Patterning (SADP) process.

Exemplarily, as illustrated in FIG. 15, the S320 may include the following steps.

At S324, the plurality of first protrusions 75 disposed at intervals are formed on the first stacked structure 70, the first protrusions 75 corresponds to the connection pads 20, and in the horizontal direction, the width of the first protrusion 75 is less than the width of the connection pad 20.

At S325, the etching layer 76 is formed on the first stacked structure 70, and the etching ratio of the etching layer 76 is greater than the etching ratio of the first stacked structure 70.

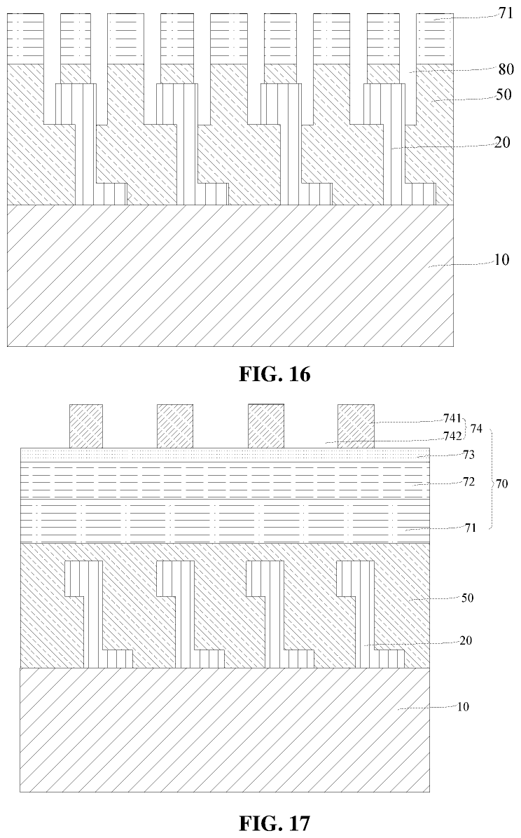

At S326, the first protrusions 75 and the etching layer 76 are removed, the annular grooves 80 penetrating through the first stacked structure 70 and extending to the dielectric structure 50 are formed, the annular groove 80 surrounds a side surface of the connection pad 20 and exposes part of top surface of the connection pad 20, part of inner side surface of the annular groove 80 is superposed with the side surface of the connection pad 20, and in the horizontal direction, the width of the etching layer 76 is equal to the sum of a width difference of the connection pad 20 and the first protrusion 75 and the width of the annular groove 80, the structure of which is as illustrated in FIG. 16.

In the step, the process of forming the annular grooves 80 is carried out by adopting the SADP process.

In some embodiments, the step of forming the first stacked structure 70 on the dielectric structure 50 may include: the first oxide layer 71, the first mask layer 72 and the first silicon oxynitride layer 73 are stacked on the dielectric structure 50 in sequence, thereby forming a structure as illustrated in FIG. 8.

The step of forming the plurality of first protrusions 75 disposed at intervals on the first stacked structure 70 may include the following operations.

At S3211, a first photoresist layer 74 is formed on the first silicon oxynitride layer 73.

The first photoresist layer 74 may be formed on the first silicon oxynitride layer 73 by adopting a coating-curing method, an ink jet printing method or a deposition method, the first photoresist layer 74 covering an upper surface of the first silicon oxynitride layer 73.

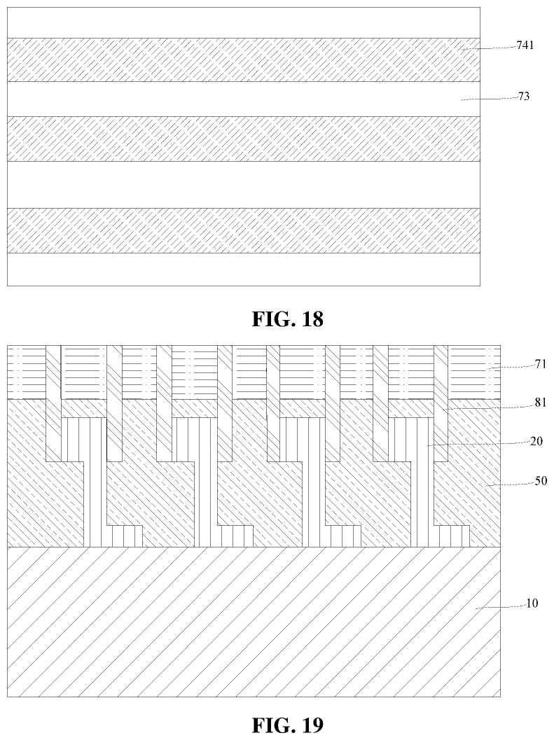

At S3212, the first photoresist layer 74 is patternized to form a first mask pattern, as illustrated in FIG. 17 and FIG. 18, the first mask pattern may include a plurality of first blocking regions 741 and a plurality of first opening regions 742 that are alternately disposed, and the plurality of first blocking regions 741 and the connection pads 20 are in one-to-one correspondence.

The first photoresist layer is patternized through patternizing treatment manners such as masking, exposing, developing and etching to form a mask pattern, i.e., a plurality of grooves disposed at intervals are formed on the first photoresist layer.

At S3213, the first mask layer 72 and the first silicon oxynitride layer 73 corresponding to the first opening region 742 are removed, the plurality of first protrusions 75 disposed on the first oxide layer 71 at intervals are formed, and the plurality of first protrusions and the connection pads are in one-to-one correspondence.

In the step, the first mask layer 72 and the first silicon oxynitride layer 73 required to be removed are eliminated by utilizing a cleaning process such as an ultrasonic cleaning method or a plasma cleaning method, so that a first mask layer 52 and the first silicon oxynitride layer 73 correspondingly disposed with the blocking region 741 are retained, thereby forming a structure as illustrated in FIG. 10.

At S330, a filler layer 81 is formed in the annular grooves 80, the upper surface of the filler layer 81 is aligned to the upper surface of the first stacked structure 70, i.e., the upper surface of the filler layer 81 is aligned to the upper surface of the first oxide layer 71.

When the annular groove 80 is configured to surround the side surface of the connection pad 20, part of inner side surface of the annular groove 80 is superposed with the side surface of the connection pad 20, and the formed filler layer 81 is circular, as illustrated in FIG. 19.

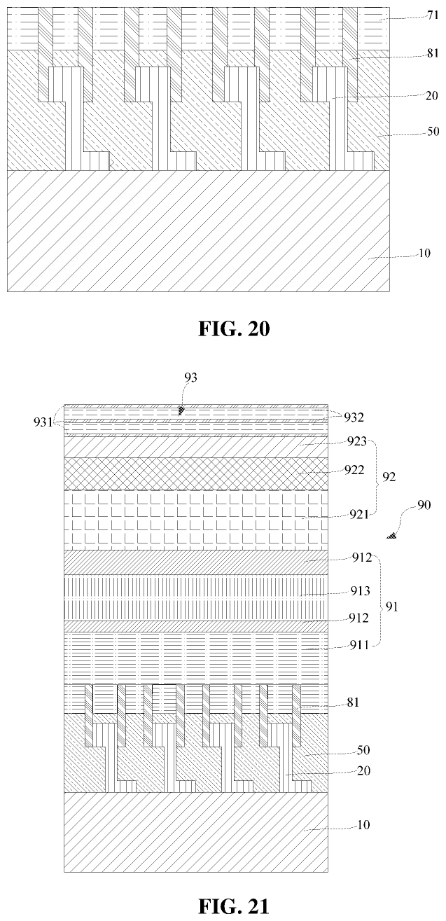

When the annular groove 80 surrounds the side surface of the connection pad 20 and exposes part of top surface of the connection pad 20, the section of the formed filler layer 81 is converse L-shaped, as illustrated in FIG. 20.

Herein, the filler layer 81 may be amorphous carbon, or, the filler layer 81 may be another medium layer, and the etching ratio of the medium layer is greater than the etching ratio of the dielectric structure.

At S340, a second stacked structure 90 is formed on the first stacked structure 70.

In the step, the second stacked structure 90 may be formed on the first stacked structure 70 through an atomic layer deposition process or a chemical vapor deposition process, i.e., the second stacked structure 90 is formed on the first oxide layer 71 through the atomic layer deposition process or the chemical vapor deposition process.

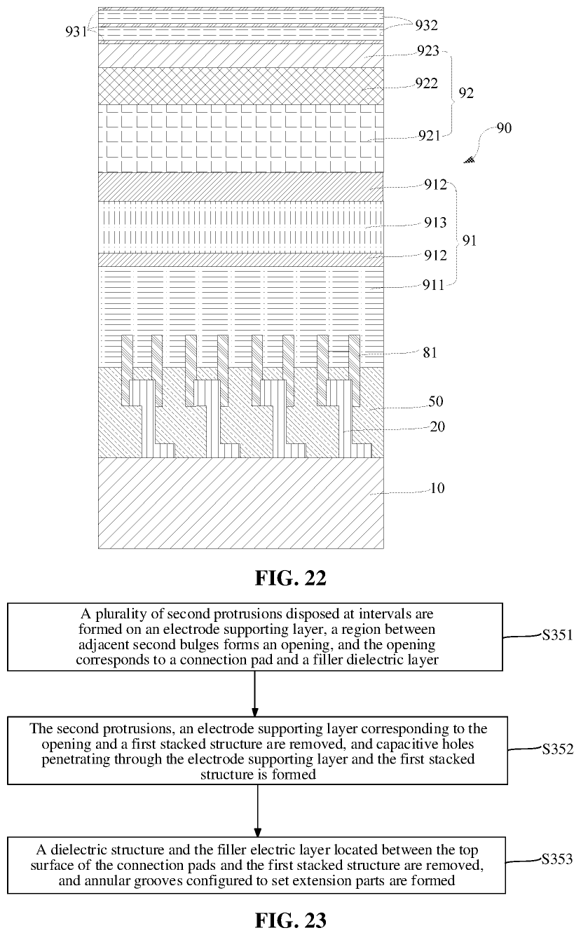

As illustrated in FIG. 21 and FIG. 22, the second stacked structure 90 may include an electrode supporting layer 91, a sacrificial layer 92 and a mask layer group 93 that are stacked in sequence, and the electrode supporting layer 91 is disposed on the first oxide layer 71.

The electrode supporting layer 91 may be a film layer composed of a single material, for example, the material of the electrode supporting layer 91 is silicon nitride. For another example, the electrode supporting layer 91 may be a plurality of film layers, moreover, materials of the various film layers are different, exemplarily, the electrode supporting layer 91 may include a second oxide layer 911, a silicon nitride layer 912, a third oxide layer 913 and a silicon nitride layer 912 that are stacked on the first stacked structure 70 in sequence, herein, the material of the second oxide layer 911 and the material of the third oxide layer 913 may be same and may also be different.

The sacrificial layer 92 may include a polycrystalline silicon layer 921, a fourth oxide layer 922 and a first carbon layer 923, and the polycrystalline silicon layer 921 is disposed on a side surface, departing from the third oxide layer 913, of the silicon nitride layer 912.

The mask layer group 93 may include a second silicon oxynitride layer 931, a second mask layer 932, a second silicon oxynitride layer 931 and a second mask layer 932 that are stacked in sequence.

In the embodiment, the etching ratio of the electrode supporting layer 91 is greater than the etching ratio of the sacrificial layer 92, and the etching ratio of the sacrificial layer 92 is greater than the etching ratio of the mask layer group 93. Because the etching ratio of the electrode supporting layer 91 is the largest, at the same etching speed, the etching depth of the electrode supporting layer 91 is the largest, so that a groove extending towards the substrate will be formed on the electrode supporting layer 91 in a subsequent etching process.

At S350, capacitive holes 31 penetrating through the second stacked structure 90 and extending to top surfaces of the respective connection pads 20 are formed, and the filler layer 81 in the annular grooves 80 is removed, so that an end, towards the substrate, of each capacitive hole 31 is communicated with the annular groove.

Exemplarily, as illustrated in FIG. 23, the S350 may include the following steps.

At S351, a plurality of second protrusions disposed at intervals are formed on the electrode supporting layer 91, a region between adjacent second protrusions forms an opening 924, and each opening 924 corresponds to a respective connection pad 20 and the filler layer 81.

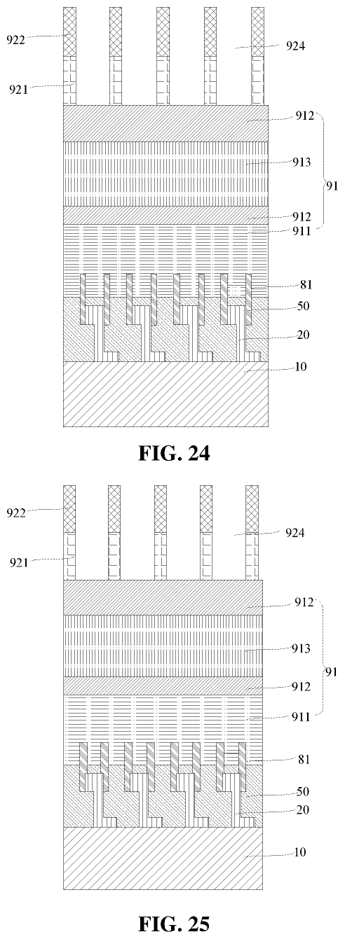

In the step, because the etching ratio of the sacrificial layer 92 is greater than the etching ratio of the mask layer group 93, at the same etching speed, the mask layer group 93 will be completely etched away, moreover, a plurality of openings 924 are formed on the sacrificial layer 92, the second protrusion is formed between adjacent openings 924, and each opening 924 corresponds to a respective connection pad 20 and the filler layer 81, thereby forming a structure as illustrated in FIG. 24 and FIG. 25.

At S352, the second protrusions, the electrode supporting layer 91 corresponding to the opening 924 and the first stacked structure 70 are removed, and the capacitive holes 31 penetrating through the electrode supporting layer 91 and the first stacked structure 70 are formed.

Etching is continuously carried out by utilizing a high-selectivity anisotropic dry etching process, so that the opening 924 continuously extends downwardly till to penetrate through the electrode supporting layer 91 and the first stacked structure 70.

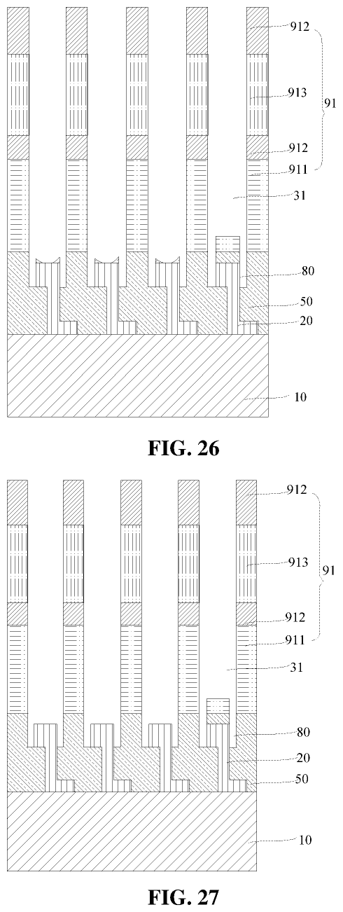

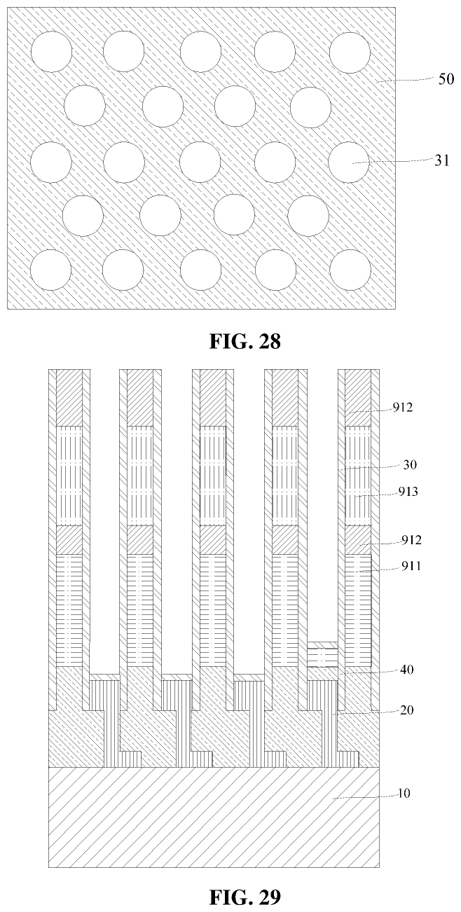

At S353, the dielectric structure 50 and the filler layer 81 located between the top surface of the connection pad 20 and the first stacked structure 70 are removed, and the annular groove 80 configured to set the extension part 40 is formed, thereby forming a structure as illustrated in FIG. 26, FIG. 27 and FIG. 28.

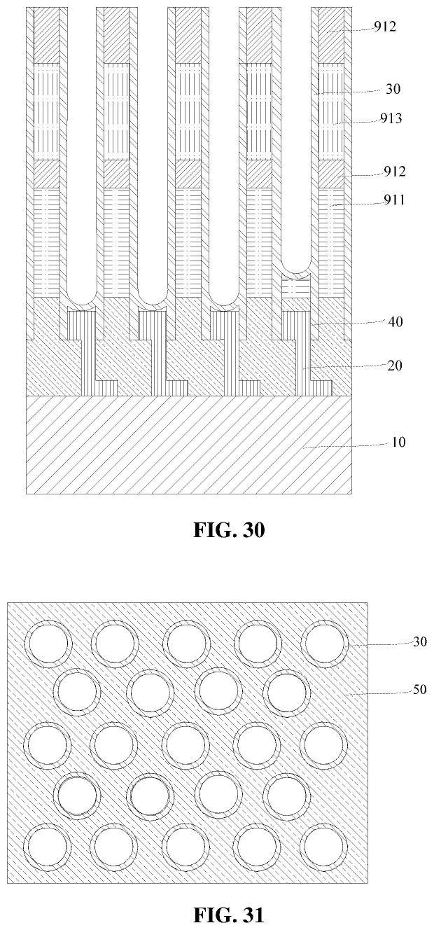

At S360, the first electrode layer 30 is formed in the capacitive hole 31 and the extension part 40 is formed in the annular groove 80, and the bottom of the first electrode layer 30 is electrically connected with the top surface of the connection pad 20. The extension part 40 covers the top surface of the connection pad 20 and the side surface of the connection pad 20, and forms an integrated structure with the first electrode layer 30, thereby forming a structure as illustrated in FIG. 29, FIG. 30 and FIG. 31.

The material of the first electrode layer 30 is deposited on the side wall of the capacitive hole 31, in the annular groove 80 and on the top surface of the connection pad 20 by adopting the atomic layer deposition process, the first electrode layer 30 and the extension part 40, that are of an integrated structure, are formed on the side wall of the capacitive hole 31, in the annular groove 80 and on the top surface of the connection pad 20. Herein, the extension part 40 covers the top surface of the connection pad 20 and the side surface of the connection pad 20, so that a contact area between the first electrode layer 30 and the connection pad 20 may be increased, contact resistance between the first electrode layer 30 and the connection pad 20 may be reduced, thus signal delay is reduced, and the performance of the DRAM is improved. Moreover, the extension part 40 may also improve the acting force between the capacitive hole and the connection pad, so that the collapse risk of the capacitor in a subsequent manufacturing process is reduced.

Moreover, the materials of the first electrode layer 30 and the extension part 40 may be one or a compound formed by metal nitride and metal silicide, such as titanium nitride, titanium silicide or titanium silicon nitride.

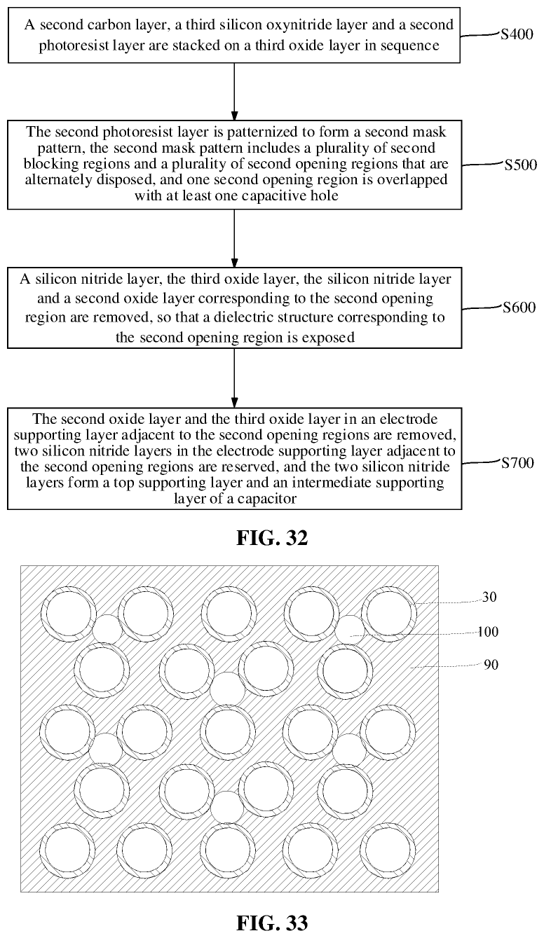

After the steps of forming the first electrode layer 30 in the capacitive hole 31 and forming the first extension part 40 in the annular groove 80, the operation may also include the following steps, as illustrated in FIG. 32.

At S400, a second carbon layer, a third silicon oxynitride layer and a second photoresist layer are stacked on the third oxide layer in sequence.

At S500, the second photoresist layer is patternized to form a second mask pattern, the second mask pattern may include a plurality of second blocking regions and a plurality of second opening regions that are alternately disposed, and one second opening region is overlapped with at least one capacitive hole.

Herein, the second opening region is overlapped with a plurality of capacitive holes. For example, as illustrated in FIG. 33, the DRAM provided by the embodiments may include a plurality of capacitive holes, every three capacitive holes form a triangular capacitive hole group, a plurality of capacitive hole groups are distributed on the dielectric structure at intervals, and the center of the second opening region is superposed with the center of the triangular capacitive hole group.

At S600, the silicon nitride layer, the third oxide layer, the silicon nitride layer and the second oxide layer corresponding to the second opening region are removed, so that the dielectric structure 50 corresponding to the second opening region 100 is exposed.

In the step, under other conditions, part of second electrode layer corresponding to the second opening region may also be removed.

At S700, the second oxide layer and the third oxide layer in the electrode supporting layer adjacent to the second opening region are removed, two silicon nitride layers in the electrode supporting layer adjacent to the second opening region are reserved, and the two silicon nitride layers form a top supporting layer and an intermediate supporting layer of the capacitor, thereby forming a structure as illustrated in FIG. 2 and FIG. 3.

According to the manufacturing method of the DRAM provided by the embodiments of the present disclosure, the extension part extending towards the substrate is formed on the first electrode layer, and the extension part is coated on the top surface and the side surface of the connection pad at the same time. Compared with the technical solution that the extension part is only coated on the top surface of the connection pad, the extension part in the embodiments of the present disclosure increases an contact area between the first electrode layer and the connection pad, reduces contact resistance between the first electrode layer and the connection pad, thus reduces signal delay of the DRAM, and improves the performance of the DRAM.

According to the DRAM and the manufacturing method thereof provided by the embodiments of the present disclosure, the first electrode layer is provided with the extension part extending towards the substrate, and the extension part is coated on the top surface and the side surface of the connection pad at the same time. Compared with the technical solution that the extension part is only coated on the top surface of the connection pad, the extension part in the embodiments of the present disclosure increases an contact area between the first electrode layer and the connection pad, reduces contact resistance between the first electrode layer and the connection pad, thus reduces signal delay of the DRAM, and improves the performance of the DRAM.

Moreover, the extension part may also increase the acting force between the capacitive hole and the connection pad, so that the collapse risk of the capacitor in the subsequent manufacturing process is reduced.

Besides the above described technical problems solved by the embodiments of the present disclosure, technical features constituting the technical solutions and beneficial effects of the technical features of these technical solutions, other technical problems solved by the DRAM and the manufacturing method thereof provided by the embodiments of the present disclosure, other technical features included in the technical solutions and beneficial effects of these technical features will be further described in detail in specific implementation modes.

Various embodiments or implementation modes in the specification are described in a progressive way, each of the embodiments focuses on the differences from other embodiments, and same and similar parts among various embodiments may be referred to each other.

In descriptions of the specification, description of referring terms such as “one implementation mode”, “some implementation modes”, “a schematic implementation mode”, “a demonstration”, “a specific demonstration”, or “some demonstrations” refers to specific features, structures, materials or features described in combination with the implementation modes or demonstrations involved in at least one implementation mode or demonstration of the present disclosure. In the specification, schematic description on the above terms not always refers to same embodiment modes or demonstrations. Moreover, the described specific features, structures, materials or features may be combined in any one or more implementation modes or demonstrations in a proper manner.

Finally, it is to be noted that the above various embodiments are only used to illustrate the technical solutions of the present disclosure, and are not limited thereto. Although the present disclosure has been described in detail with reference to the foregoing various embodiments, those skilled in the art should understand that the technical solutions described in the foregoing various embodiments still may be modified, or part or all technical features are equivalently replaced, but the modifications and replacements do not make the essence of the corresponding technical solutions depart from the scope of the technical solutions of various embodiments of the present disclosure.

1. A Dynamic Random Access Memory (DRAM), comprising:
a substrate;
connection pads, disposed on the substrate, each connection pad having a bottom surface towards the substrate and a top surface away from the substrate, and the bottom surface of the connection pad making contact with the substrate; and
capacitors, each capacitor being disposed on a respective connection pad and having a first electrode layer, the first electrode layer having an extension part extending towards the substrate, and the extension part being coated on a top surface and a side surface of the respective connection pad.

2. The DRAM according to claim 1, wherein
the extension part comprises a first extension part and a second extension part connected with the first extension part, the first extension part is coated on a top surface of the connection pad, the second extension part is coated on a side surface of the connection pad, and the first extension part and the second extension part have an included angle, which is between 50 degrees and 90 degrees.

3. The DRAM according to claim 1, wherein each capacitor further comprises a second electrode layer which is disposed in a layer different from a layer where the first electrode layer is located, the second electrode layer is disposed on one side, away from the substrate, of the first electrode layer, and has an overlapped region with the first electrode layer; and
a dielectric layer is disposed between the first electrode layer and the second electrode layer.

4. The DRAM according to claim 1, wherein a dielectric structure is disposed between the substrate and the capacitors, and the connection pads are disposed in the dielectric structure;
capacitor contact windows are disposed within the substrate, and the bottom surface of each connection pad is electrically connected with a respective capacitor contact window.

5. The DRAM according to claim 4, wherein each connection pad comprises a first connection part and a second connection part, and a transition part disposed between the first connection part and the second connection part and respectively connected with the first connection part and the second connection part, wherein the first connection part is electrically connected with the capacitor contact window, and the second connection part is electrically connected with the first electrode layer;
a plane parallel to the substrate is used as a section, and an area of a section of the transition part is smaller than an area of a section of the first connection part and smaller than an area of a section of the second connection part.

6. The DRAM according to claim 5, wherein each extension part covers a top surface where a respective second connection part makes contact with a respective first electrode layer, and covers a side surface of the respective second connection part.

7. The DRAM according to claim 4, wherein a plurality of capacitors and a supporting layer for separating the plurality of capacitors are disposed on the dielectric structure.

8. A manufacturing method of a Dynamic Random Access Memory (DRAM), comprising steps of:
providing a substrate;
forming connection pads on the substrate, each connection pad having a bottom surface towards the substrate and a top surface away from the substrate, and the bottom surface of the connection pad making contact with the substrate; and
forming capacitors on respective connection pads, each capacitor having a first electrode layer, the first electrode layer having an extension part extending towards the substrate, and the extension part covering a top surface and a side surface of a respective connection pad.

9. The manufacturing method of the DRAM according to claim 8, wherein
before the step of forming the connection pads on the substrate, the manufacturing method further comprises: forming a dielectric structure on the substrate;
the step of forming the capacitors on the respective connection pads comprises:
forming a first stacked structure on the dielectric structure;
forming annular grooves penetrating through the first stacked structure and extending into the dielectric structure;
forming a filler layer in each annular groove, an upper surface of the filler layer being aligned to an upper surface of the first stacked structure;
forming a second stacked structure on the first stacked structure;
forming capacitive holes penetrating through the second stacked structure and extending to top surfaces of respective connection pads, and removing the filler layers in the annular grooves, so that an end, towards the substrate, of each capacitive hole is communicated with the respective annular groove; and
forming the first electrode layer in each capacitive hole and forming the extension part in each annular groove, a bottom of the first electrode layer being electrically connected with a top surface of the connection pad, and the extension part covering the top surface of the connection pad and the side surface of the connection pad and forming an integrated structure with the first electrode layer.

10. The manufacturing method of the DRAM according to claim 9, wherein
the step of forming the annular grooves penetrating through the first stacked structure and extending into the dielectric structure comprises:
forming a plurality of first protrusions disposed at intervals on the first stacked structure, the first protrusion corresponding to the respective connection pads, and in a horizontal direction, a width of the first protrusion being equal to a width of the connection pad;
forming an etching layer on the first stacked structure, an etching ratio of the etching layer being greater than an etching ratio of the first stacked structure; and
removing the first protrusions and the etching layer to form the annular grooves penetrating through the first stacked structure and extending to the dielectric structure, each annular groove being configured to surround the side surface of the respective connection pad, part of inner side surface of the annular groove being superposed with the side surface of the respective connection pad, and in the horizontal direction, a width of the annular groove being equal to a width of the etching layer.

11. The manufacturing method of the DRAM according to claim 9, wherein
the step of forming the annular grooves penetrating through the first stacked structure and extending into the dielectric structure comprises:
forming a plurality of first protrusions disposed at intervals on the first stacked structure, each first protrusion corresponding to a respective connection pad, and in a horizontal direction, a width of the first protrusion being less than a width of the connection pad;
forming an etching layer on the first stacked structure, an etching ratio of the etching layer being greater than an etching ratio of the first stacked structure; and
removing the first protrusions and the etching layer to form the annular grooves penetrating through the first stacked structure and extending to the dielectric structure, each annular groove surrounding a side surface of the respective connection pad and exposing part of top surface of the respective connection pad, part of inner side surface of the annular groove being superposed with the side surface of the respective connection pad, and in the horizontal direction, a width of the etching layer being equal to a sum of: a difference between the width of the connection pad and the width of the first protrusion, and a width of the annular groove.

12. The manufacturing method of the DRAM according to claim 10, wherein
the step of forming the first stacked structure on the dielectric structure comprises: forming a first oxide layer, a first mask layer and a first silicon oxynitride layer on the dielectric structure in a sequentially stacked manner;
the step of forming the plurality of first protrusions disposed at intervals on the first stacked structure comprises:
forming a first photoresist layer on the first silicon oxynitride layer;
patternizing the first photoresist layer to form a first mask pattern, the first mask pattern comprising a plurality of first blocking regions and a plurality of first opening regions that are alternately disposed, and the plurality of first blocking regions and the connection pads being in one-to-one correspondence; and
removing the first mask layer and the first silicon oxynitride layer corresponding to the first opening regions to form the plurality of first protrusions disposed on the first oxide layer at intervals, the plurality of first protrusions and the connection pads being in correspondence.

13. The manufacturing method of the DRAM according to claim 12, wherein the step of forming a second stacked structure on the first stacked structure comprises:
forming an electrode supporting layer, a sacrificial layer and a mask layer group on the first stacked structure in a sequentially stacked manner, an etching ratio of the electrode supporting layer being greater than an etching ratio of the sacrificial layer, and the etching ratio of the sacrificial layer being greater than an etching ratio of the mask layer group;
the step of forming capacitive holes penetrating through the second stacked structure and extending to a top surface of the connection pad, and removing the filler layer in the annular grooves, so that an end, towards the substrate, of each capacitive hole is communicated with the respective annular groove, comprises:
forming a plurality of second protrusions disposed at intervals on the electrode supporting layer, and forming an opening by a region between adjacent second protrusions, the opening corresponding to the respective connection pad and the respective filler layer;
removing the second protrusions, the electrode supporting layer corresponding to the openings and the first stacked structure to form the capacitive holes penetrating through the electrode supporting layer and the first stacked structure; and
removing the dielectric structure and the filler layer located between top surfaces of the connection pads and the first stacked structure to form the annular grooves configured to set extension parts.

14. The manufacturing method of the DRAM according to claim 13, wherein the step of forming the electrode supporting layer, the sacrificial layer and the mask layer group on the first stacked structure in a sequentially stacked manner comprises:
forming a second oxide layer, a silicon nitride layer, a third oxide layer and a silicon nitride layer on the first stacked structure in a sequentially stacked manner;
sequentially stacking a polycrystalline silicon layer, a fourth oxide layer and a first carbon layer on a side surface, departing from the third oxide layer, of the silicon nitride layer; and
sequentially stacking a second silicon oxynitride layer, a second mask layer, a second silicon oxynitride layer and a second mask layer on the first carbon layer.

15. The manufacturing method of the DRAM according to claim 14, wherein after the step of forming a first electrode layer in capacitive holes and forming extension parts in an annular grooves, the manufacturing method further comprises:
sequentially stacking a second carbon layer, a third silicon oxynitride layer and a second photoresist layer on the third oxide layer;
patternizing the second photoresist layer to form a second mask pattern, the second mask pattern comprising a plurality of second blocking regions and a plurality of second opening regions that are alternately disposed, and one second opening region being overlapped with at least one capacitive hole;
removing the silicon nitride layer, the third oxide layer, the silicon nitride layer and the second oxide layer corresponding to the second opening regions, so that the dielectric structure corresponding to the second opening regions is exposed, and part of second electrode layer corresponding to the second opening regions is removed; and
removing the second oxide layer and the third oxide layer in the electrode supporting layer adjacent to the second opening regions, and retaining two silicon nitride layers in the electrode supporting layer adjacent to the second opening regions.
